(19) United States
(12) Patent Application Publication
(10) Pub. No.: US 2025/0154398 A1
(43) Pub. Date: May 15, 2025

(54) METHOD FOR PRODUCING ABRASIVE GRAINS, COMPOSITION FOR CHEMICAL MECHANICAL POLISHING, AND POLISHING METHOD

(71) Applicant: JSR CORPORATION, Tokyo (JP)

(72) Inventors: Takanori YANAGI, Tokyo (JP); Pengyu WANG, Tokyo (JP); Koji NAKANISHI, Tokyo (JP)

(73) Assignee: JSR CORPORATION, Tokyo (JP)

(21) Appl. No.: 18/840,479

(22) PCT Filed: Mar. 10, 2023
(86) PCT No.: PCT/JP2023/009228

§ 371 Date: Aug. 21, 2024

(30) Foreign Application Priority Data
Mar. 28, 2022 (JP) 2022-051381

(51) Int. Cl. C09K 3/14

(52) U.S. Cl. CPC C09K 3/1454

(57) ABSTRACT

The present invention provides: a composition for chemical mechanical polishing, a polishing method which uses this composition for chemical mechanical polishing, and a method for producing abrasive grains which are used therein. The present invention also provides: a composition for chemical mechanical polishing, the composition being capable of polishing a silicon oxide film at a high polishing rate, while having excellent storage stability; a polishing method which uses this composition for chemical mechanical polishing; and a method for producing abrasive grains which are used therein. A method for producing abrasive grains according to the present invention comprises a step in which particles each having a surface to which a hydroxyl group (—OH) is immobilized via a covalent bond, an alkoxysilane having an epoxy group, and a basic compound are mixed and heated.

### TECHNICAL FIELD

The invention relates to a method for producing abrasive grains, a composition for chemical mechanical polishing, and a polishing method.

### RELATED ART

With the advancing of the technology for producing semiconductor integrated circuits, there is a demand for higher integration and faster operation of semiconductor elements. Together with this, the flatness requirement on the semiconductor substrate surface in the production process of fine circuits in semiconductor elements is becoming increasingly strict, and chemical mechanical polishing (hereinafter also referred to as “CMP”) has become an essential technique in the production process of semiconductor devices.

For example, in a contact hole for electrically bonding wires in the upper-lower vertical direction, tungsten, which has excellent embedding properties, is used. For example, Patent Documents 1 to 3 have proposed compositions for chemical mechanical polishing used for polishing a redundant tungsten film on an insulation film.

### CITATION LIST

### Patent Literature

Patent Document 1: Japanese Laid-open No. 2005-518091
Patent Document 2: Japanese Laid-open No. 2007-19093
Patent Document 3: Japanese Laid-open No. 2008-503875

### SUMMARY OF INVENTION

### Technical Problem

In the composition for chemical mechanical polishing used for polishing the tungsten film, when silica is used as abrasive grains, the polishing rate of the silicon oxide film tends to be fast by reacting silica with the silicon oxide film, and selective polishing of the tungsten film is difficult. In addition, silica tends to aggregate in a liquid other than in a basic liquid, and the storage stability of the composition for chemical mechanical polishing may be damaged easily.

Several aspects according to the invention provide a composition for chemical mechanical polishing capable of selectively polishing the tungsten film by increasing the polishing rate of the tungsten film with respect to the silicon oxide film and having excellent storage stability, as well as a polishing method using the same.

Meanwhile, in the composition for chemical mechanical polishing used for polishing the silicon oxide film, when silica is used as abrasive grains, silica tends to aggregate in a liquid other than in a basic liquid, and the storage stability of the composition for chemical mechanical polishing may be easily damaged. Therefore, in the composition for chemical mechanical polishing whose liquid property is acidic, due to the aggregation of the abrasive grains, the polishing rate of the silicon oxide film tends to decrease.

Several aspects according to the invention also provide a composition for chemical mechanical polishing capable of polishing a silicon oxide film at a high speed and having excellent storage stability, as well as a polishing method using the same.

In addition, according to several aspects of the invention, a method for producing abrasive grains used in the composition for chemical mechanical polishing is provided.

### Solution to Problem

According to an aspect of a method for producing abrasive grains according to an embodiment of the invention, the method includes a process of mixing and heating: particles each having a surface to which a hydroxyl group (—OH) is immobilized via a covalent bond; an alkoxysilane having an epoxy group; and a basic compound.

In an aspect of the method for producing the abrasive grains, the method may also include: a first process of heating a mixture containing the particles each having the surface to which the hydroxyl group (—OH) is immobilized via the covalent bond and the alkoxysilane having the epoxy group; and a second process of, after the first process, further adding the basic compound and performing heating.

In any of the aspects of the method for producing the abrasive grains, the method may further include: a third process of, after the second process, further adding an alkoxysilane having an alkyl group and performing heating.

In any of the aspects of the method for producing the abrasive grains, it may also be that: the basic compound is at least one selected from a group consisting of ammonia and a compound having an amino group.

In any of the aspects of the method for producing the abrasive grains, it may also be that: the abrasive grains are provided with a portion of a structure represented by Formula (1) below on a surface of the abrasive grain.

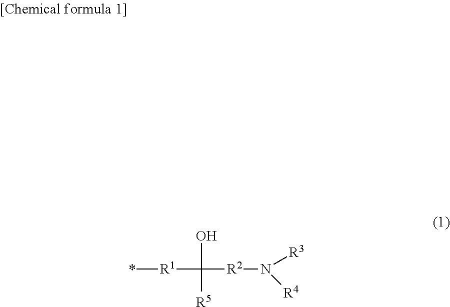

(In Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.)

In any of the aspects of the method for producing the abrasive grains, it may also be that: the abrasive grains have a portion of a structure represented by Formula (2) below and an alkyl group.

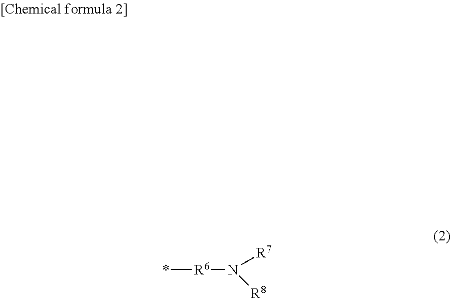

(In Formula (2), R⁶ represents a divalent organic group having a carbon number of 1 or more, R⁷ and R⁸ are each independently a hydrogen atom or a monovalent organic group having a carbon number of 1 or more, and * represents a bond.)

In any of the aspects of the method for producing the abrasive grains, it may also be that: in the composition for chemical mechanical polishing that contains the abrasive grains, a zeta potential of the abrasive grains is 10 mV or more.

An aspect of a composition for chemical mechanical polishing according to the invention includes: abrasive grains produced according to the method according to any one of the above; and a liquid medium.

An aspect of a composition for chemical mechanical polishing according to the invention includes: abrasive grains, and a liquid medium. The abrasive grains are provided with a portion of a structure represented by Formula (1) below on a surface of the abrasive grain.

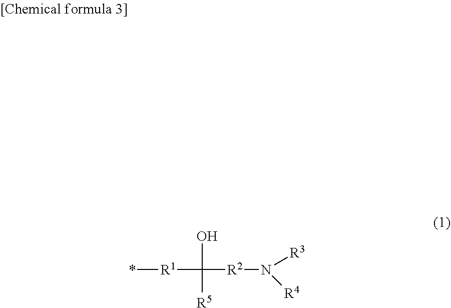

(In Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.)

An aspect of a composition for chemical mechanical polishing according to the invention includes: abrasive grains, and a liquid medium, and the abrasive grains have a portion of a structure represented by Formula (2) below and an alkyl group.

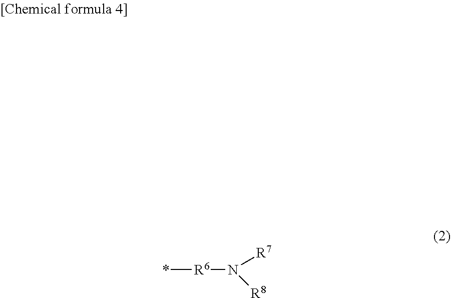

(In Formula (2), R⁶ represents a divalent organic group having a carbon number of 1 or more, R⁷ and R⁸ are each independently a hydrogen atom or a monovalent organic group having a carbon number of 1 or more, and * represents a bond.)

In an aspect of the composition for chemical mechanical polishing according to any of the aspects, it may also be that: pH is 2 or more and 5 or less.

In an aspect of the composition for chemical mechanical polishing according to any of the aspects, it may also be that: the composition may include an acidic compound, an iron (III) compound, and an oxidization agent.

An aspect of the composition for chemical mechanical polishing according to any of the aspects may be used for polishing a silicon oxide film.

An aspect of the composition for chemical mechanical polishing according to any of the aspects may be used for selectively polishing a tungsten film.

An aspect of a polishing method according to the invention includes: a process of polishing a silicon oxide film by using the composition for chemical mechanical polishing according to any of the aspects.

An aspect of a polishing method according to the invention includes: a process of selectively polishing a tungsten film by using the composition for chemical mechanical polishing according to any of the aspects.

### Effects of Invention

According to an aspect of the composition for chemical mechanical polishing, since the polishing rate of the tungsten film with respect to the silicon oxide film can be increased, the tungsten film can be selectively polished, and the storage stability is excellent. In addition, according to the method for producing abrasive grains according to the invention, the tungsten film can be selectively polished with respect to the silicon oxide film, and abrasive grains with excellent storage stability in the composition for chemical mechanical polishing can be produced.

According to an aspect of the composition for chemical mechanical polishing, the polishing rate with respect to the silicon oxide film can be increased, and the storage stability is excellent. In addition, according to the method for producing abrasive grains according to the invention, abrasive grains having excellent storage stability in the composition for chemical mechanical polishing and able to polish the silicon oxide film at a high speed can be produced.

### BRIEF DESCRIPTION OF DRAWINGS

FIG. 1 is a schematic cross-sectional view illustrating a processed workpiece suitable for use in a polishing method according to an embodiment.

FIG. 2 is a schematic cross-sectional view illustrating a polishing method according to an embodiment.

FIG. 3 is a schematic perspective view illustrating a chemical mechanical polishing device.

### DESCRIPTION OF EMBODIMENTS

In the following, preferable embodiments of the invention are described in detail. Nevertheless, the invention is not limited to the following embodiments, and includes various modified examples implemented within the scope without deviating from the gist of the invention.

In the specification, the term “ . . . (meth)acrylic acid” is a concept that encompasses both “ . . . acrylic acid” and “ . . . methacrylic acid”. Likewise, the term “(meth)acrylamide” is a term that encompasses both “acrylamide” and “methacrylamide.”

In the specification, the numerical range recited by using “X-/to Y” includes the value X as the lower limit and includes the value Y as the upper limit.

### 1. METHOD FOR PRODUCING ABRASIVE GRAINS

A method for producing abrasive grains according an embodiment of the invention includes a process of mixing and heating particles each having a surface to which a hydroxyl group (—OH) is immobilized via a covalent bond, an alkoxysilane having an epoxy group, and a basic compound. According to the method for producing the abrasive grains according to the embodiment, abrasive grains for selectively polishing a tungsten film with respect to a silicon oxide film can be produced. In addition, according to the method for producing the abrasive grains, abrasive grains for polishing the silicon oxide film at a high speed can be produced.

According to the method for producing the abrasive grains according to an embodiment of the invention, abrasive grains having a portion of the structure represented by Formula (1) below can be obtained by mixing and heating the particles each having a surface to which a hydroxyl group (—OH) is immobilized via a covalent bond, an alkoxysilane having an epoxy group, and a basic compound. The mixing method is not particularly limited, and may include a first process of heating a mixture containing the particles each having the surface to which the hydroxyl group (—OH) is immobilized via the covalent bond and the alkoxysilane having the epoxy group and a second process of, after the first process, further adding and heating the basic compound. Through the first process and the second process, the side reaction of each component can be suppressed.

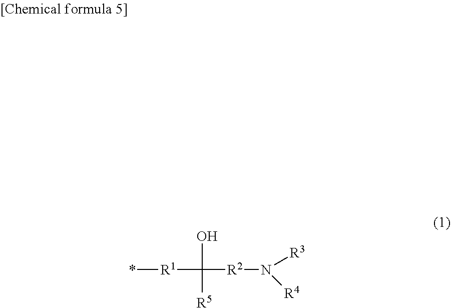

(In Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.)

In the following, each process for the method for producing the abrasive grains according to the embodiment will be described in detail.

### 1.1. First Process

The first process is a process of heating the mixture containing the particles each having the surface to which the hydroxyl group (—OH) is immobilized via the covalent bond and the alkoxysilane having the epoxy group. Through the first process, it is possible to produce particles having the surfaces to which organic groups having epoxy groups are immobilized.

The heating temperature in the first process can be set between the room temperature and 100° C., and preferably between 40° C. and 80° C. The heating time can be set between 10 minutes and 24 hours, and preferably 30 minutes and 12 hours.

In the first process, the particles each having the surface to which the hydroxyl group (—OH) is immobilized via the covalent bond are used. The particles each having the surface to which the hydroxyl group (—OH) is immobilized via the covalent bond do not include particles having the surfaces to which compounds having hydroxyl groups are physically or ionically absorbed to the surfaces.

The material of the particles as the raw material of the abrasive grains is not particularly limited, and examples may include inorganic oxides such as silica, ceria, alumina, zirconia, and titania. Among the above, silica is preferred. As silica, for example, examples may include fumed silica, colloidal silica, etc. From the perspective of reducing polishing defects such as scratches, colloidal silica is preferred. Colloidal silica has a hydroxyl group on the surface, such as Si—OH, and the product produced by using the method disclosed in Japanese Laid-open No. 2003-109921, for example, can be used.

In the first process, the alkoxysilane having the epoxy group is used. As the alkoxysilane having the epoxy group, it is not particularly limited as long as a compound is capable of generating a silanol group by hydrolyzing an alkoxyl group and reacting, through a dehydration condensation reaction, with the hydroxyl group (—OH) immobilized on the particle surface, thereby being bonded to the particle surface. By reacting with the alkoxysilane having the epoxy group, the organic group having the epoxy group can be simply immobilized on the particle surface.

As the alkoxysilane having the epoxy group, an alkoxysilzne having two or three alkoxyl groups bonded to silicon atoms can be preferably used. As the alkoxyl group, a lower alkoxyl group such as a methoxy group, an ethoxy group, a propoxy group, and a butoxy group, etc., are preferred, and a methoxy group, an ethoxy group are more preferred. As the epoxy group, a glycidoxyalkyl group is preferred, and an epoxy group in a glycidoxypropyl group is more preferred.

As a specific example of the alkoxysilane having the epoxy group, glycidoxyalkyltrialkoxysilane, glycidoxyalkyldialkoxysilane, 2-(3,4-epoxycyclohexyl)alkyltrialkoxysilane are preferred. As the glycidoxyalkyltrialkoxysilane, examples may include 3-glycidoxypropyltrimethoxysilane, 3-glycidoxypropyltriethoxysilane, etc.

As the glycidoxyalkyldialkoxysilane, examples may include 3-glycidoxypropyl(methyl)dimethoxysilane, 3-glycidoxypropyl(methyl)diethoxysilane, etc. As the 2-(3,4-epoxycyclohexyl)alkyltrialkoxysilane, examples may include 2-(3,4-epoxycyclohexyl)ethyltrimethoxysilane, 2-(3,4-epoxycyclohexyl)ethyltriethoxysilane, etc. Among the above, 3-glycidoxypropyltrimethoxysilane, 3-glycidoxypropyltriethoxysilane are more preferred. One type of the alkoxysilanes having the epoxy group may be used alone, or two or more types of alkoxysilanes having the epoxy group may be used together.

### 1.2. Second Process

The second process is a process of adding and heating the particles having the surfaces to which the organic groups having the epoxy groups are immobilized are immobilized via the covalent bonds, as obtained in the first process, as well as the basic compound. By adding an appropriate amount of the basic compound with respect to the particles as obtained in the first process and having the surfaces to which the organic groups having the epoxy groups are immobilized via the covalent bonds and performing heating, the epoxy groups immobilized to the surfaces and the basic compounds undergo a ring opening reaction and are converted into a group represented by Formula (1) or a group represented by Formula (2) below.

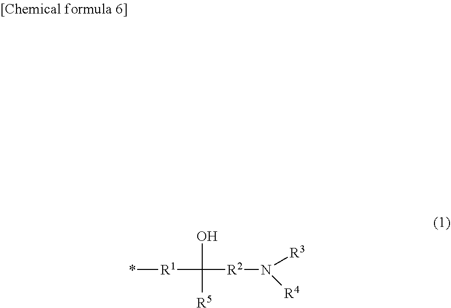

(In Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.)

In the case where R¹ is a divalent organic group having the carbon number of 1 or more, R¹ preferably has a structure represented as follows:

—(CH₂)ₙO—

(n being an integer of 1 or more)

The divalent organic group having the carbon number of 1 or more as represented by R² may be any one of a divalent aliphatic hydrocarbon group, a divalent aromatic hydrocarbon group, a divalent araliphatic hydrocarbon group, or a divalent alicyclic hydrocarbon group, and may be linear or branched, and R² preferably has a structure represented as follows:

—(CH₂)ₙ—

(n being an integer of 1 or more).

As the monovalent organic group having a carbon number of 1 or more as represented by R³, R⁴, and R⁵ may be any one of a monovalent aliphatic hydrocarbon group, a monovalent aromatic hydrocarbon group, a monovalent araliphatic hydrocarbon group, or a monovalent alicyclic hydrocarbon group. In addition, the aliphatic groups in the aliphatic hydrocarbon groups and the araliphatic hydrocarbon groups may be saturated or unsaturated, and may be linear or branched. As such hydrocarbon groups, for example, examples may include linear, branched, or cyclic alkyl groups, alkenyl groups, alkynyl groups, cycloalkyl groups, aralkyl groups, aryl groups, etc.

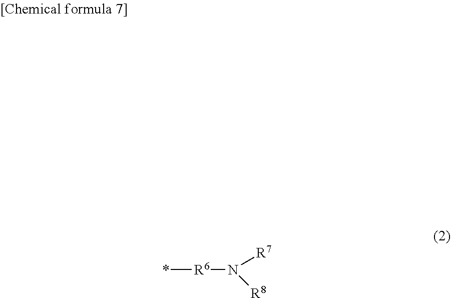

(In Formula (2), R⁶ represents a divalent organic group having a carbon number of 1 or more, R⁷ and R⁸ are each independently a hydrogen atom or a monovalent organic group having a carbon number of 1 or more, and * represents a bond.)

As the divalent organic group having a carbon number of 1 or more as represented by R⁶, a group represented by Formula (3) as follows is preferred.

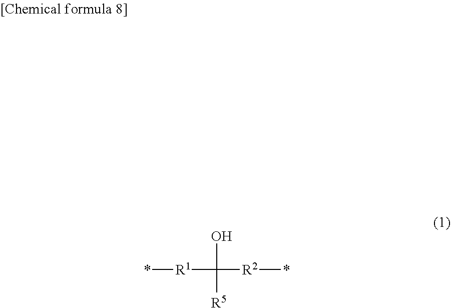

(In Formula (3), R¹, R², and R⁵ have the same meanings as R¹, R², and R⁵ in Formula (1), and * represents a bond.)

In the case where R¹ is a divalent organic group having the carbon number of 1 or more, R¹ preferably has a structure represented as follows:

—(CH₂)ₙO—

(n being an integer of 1 or more).

The divalent organic group having the carbon number of 1 or more as represented by R² may be any one of a divalent aliphatic hydrocarbon group, a divalent aromatic hydrocarbon group, a divalent araliphatic hydrocarbon group, or a divalent alicyclic hydrocarbon group, and may be linear or branched, and R² preferably has a structure represented as follows:

—(CH₂)ₙ—

(n being an integer of 1 or more).

In Formula (2), as the monovalent organic group having a carbon number of 1 or more as represented by R⁷ and R⁸ may be any one of a monovalent aliphatic hydrocarbon group, a monovalent aromatic hydrocarbon group, a monovalent araliphatic hydrocarbon group, or a monovalent alicyclic hydrocarbon group. In addition, the aliphatic groups in the aliphatic hydrocarbon groups and the araliphatic hydrocarbon groups may be saturated or unsaturated, and may be linear or branched. As such hydrocarbon groups, for example, examples may include linear, branched, or cyclic alkyl groups, alkenyl groups, alkynyl groups, cycloalkyl groups, aralkyl groups, aryl groups, etc.

The heating temperature in the second process can be set between the room temperature and 100° C., and preferably between 40° C. and 80° C. The heating time can be set between 10 minutes and 24 hours, and preferably 30 minutes and 12 hours.

The basic compound is not particularly limited as long as the compound is capable of undergoing a ring opening reaction with the epoxy group immobilized onto the particle surface to be converted into a group represented by Formula (1) or a group represented by Formula (2), but is preferably ammonia or a compound having an amino group.

In the case where ammonia is added as the basic compound, ammonia is preferably added as ammonia water with a concentration of 1 mass % to 30 mass %.

As the compound having the amino group, for example, isopropylamine, amylamine, isoamylamine, dibutylamine, monoethanolamine, tetramethylammonium hydroxide, tetraethylammonium hydroxide, tetrabutylammonium hydroxide, benzylamine, methylamine, ethylenediamine, diglycolamine are preferred.

In the second process, one type of the basic compounds may be used alone, or two or more types of the basic compounds may be used together.

### 1.3. Third Process

The method for producing the abrasive grains according to the embodiment may further include a third process of heating, after the second process, an alkoxysilane having an alkyl group. By adding, in an appropriate amount, the alkoxysilanes having the alkyl groups to the particles having the groups represented in Formula (1) or the groups represented by Formula (2) on the surface and performing heating, the alkyl groups are introduced onto the particle surfaces in addition to the groups represented by Formula (1) or the groups represented by Formula (2). Such abrasive grains having the surfaces onto which the alkyl groups are introduced become hydrophobic by reducing the number of silanol groups on the surfaces. Accordingly, the polishing rate ratio of the silicon oxide film with respect to the tungsten film can be reduced. Thus, the tungsten film can be further selectively polished.

The heating temperature in the third process can be set between the room temperature and 100° C., and preferably between 40° C. and 80° C. The heating time can be set between 10 minutes and 24 hours, and preferably between 30 minutes and 12 hours.

In the third process, the alkoxysilane having the alkyl group is used. The alkoxysilane having the alkyl group is a component different from the alkoxysilane having the epoxy group used in the first process. As the alkoxysilane having the alkyl group, the chemical compound is not particularly limited, as long as a silanol group can be generated by hydrolyzing an alkoxyl group, the silanol group can undergo a dehydration condensation reaction and be bonded to the hydroxyl group (—OH) that remains on the particle surface without reacting in the first process on the particle surface, and the alkyl group can be immobilized on the particle surface. By reacting with the alkoxysilane having the alkyl group, the alkyl group can be simply immobilized onto the particle surface.

The alkoxysilane having the alkyl group preferably has one or two alkyl groups bonded to a silicon atom. As the alkoxyl group, examples can include lower alkoxyl groups such as a methoxy group, an ethoxy group, a propoxy group, a butoxy group, etc. However, a methoxy group, an ethoxy group are preferred. In addition, as the alkyl group, examples may include methyl groups, ethyl groups, propyl groups, isopropyl groups, butyl groups, isobutyl groups, sec-butyl groups, tert-butyl groups, cyclohexyl groups, n-octyl groups, etc.

Specific examples of the alkoxysilane having the alkyl group may include: methyltrimethoxysilane, dimethyldimethoxysilane, ethyltrimethoxysilane, diethyldimethoxysilane, ethyltriethoxysilane, diethyldiethoxysilane, n-butyltrimethoxysilane, cyclohexyltrimethoxysilane, n-octyltrimethoxysilane, etc. One type of the alkoxysilanes having the alkyl groups may be used alone, or two or more types of alkoxysilanes having the alkyl groups may be used together.

### 1.4 Properties of Abrasive Grains

The abrasive grains obtained through the method according to the embodiment exhibit the properties as follows.

### 1.4. 1 Zeta Potential

The zeta potential of the abrasive grains in the composition for chemical mechanical polishing as produced by the method according to the embodiment is preferably 10 mV or more, more preferably 15 mV or more, and particularly preferably 20 mV or more. In addition, the zeta potential is preferably 40 mV or less, and more preferably 35 mV or less. The abrasive grains produced by using the method according to the embodiment can be used by being added to the composition for chemical mechanical polishing to be described afterwards. When the zeta potential of the abrasive grains is within the above range, the aggregation of the particles can be effectively prevented due to the electrostatic repulsion force among the abrasive grains, and the tungsten film can be polished at a more stable polishing rate. In order to obtain the zeta potential in the range, the pH of the composition for chemical mechanical polishing is preferably set to be 2 or more and 5 or less. In order to make the zeta potential of the abrasive grains 10 mV or more in any region in which the pH of the composition for chemical mechanical polishing is 2 or more and 5 or less, for example, the usage amount of the alkoxysilane having the epoxy group used in the first process or the basic compound used in the second process can be adjusted by increasing or decreasing the usage amount.

The zeta potential of the abrasive grains can be measured through a conventional process by using a zeta potential measurement device adopting the laser Doppler method as the measurement principle. As such zeta potential measurement device, for example, examples may include “Zeta Potential Analyzer” manufactured by Brookhaven Instruments, “ELSZ-1000ZS” manufactured by Otsuka Electronics Co., Ltd., “DT-300” manufactured by Dispersion Technology, etc.

### 1.4.2 Average Secondary Particle Size

The average secondary particle size of the abrasive grains produced by the method according to the embodiment is preferably 30 nm or more, more preferably 40 nm or more, and particularly 50 nm or more. The average secondary particle size of the abrasive grains produced by the method according to the embodiment is preferably 100 nm or less, more preferably 95 nm or less, and particularly 90 nm or less. The average secondary particle size of the abrasive grains can be measured by using a dynamic light scattering particle size distribution measurement device. As such dynamic light scattering particle size distribution measurement device, examples may include “nano-particle analyzer SZ-100” manufactured by Horiba Ltd.

### 2. COMPOSITION FOR CHEMICAL MECHANICAL POLISHING

The composition for chemical mechanical polishing according to an embodiment of the invention contains the abrasive grains produced according to the above and a liquid medium. In the following, the respective components contained in the composition for chemical mechanical polishing according to the embodiment will be described in detail.

### 2.1. Abrasive Grains

The composition for chemical mechanical polishing according to the embodiment contains the abrasive grains produced according to the above method. As the abrasive grains produced according to the above methods, two examples are described in the following.

### 2.1.1. First Example

The abrasive grains according to the first example undergo the first process and the second process described above, and have a portion of the structure represented in Formula (1) below on the surface of the abrasive grain.

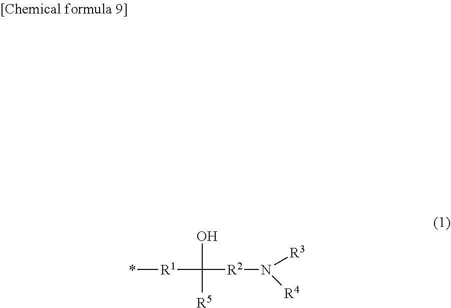

(In Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.)

By providing the amino group on the surface, the abrasive grains of the first example have a zeta potential of 10 mV or more in the acidic composition for chemical mechanical polishing. Therefore, in the acidic composition for chemical mechanical polishing, the storage stability is facilitated due to the electrostatic repulsion force among the abrasive grains. In addition, with the composition for chemical mechanical polishing containing an acidic compound, an iron (III) compound, and an oxidization agent in addition to the abrasive grains of the first example, the polishing rate of the tungsten film with respect to the silicon oxide film is significantly increased, so the tungsten film can be polished selectively.

### 2.1.2 Second Example

The abrasive grains according to the second example undergo the first process, the second process, and the third process described above, and have a portion of the structure represented in Formula (2) below on the surface of the abrasive grain and the alkyl group.

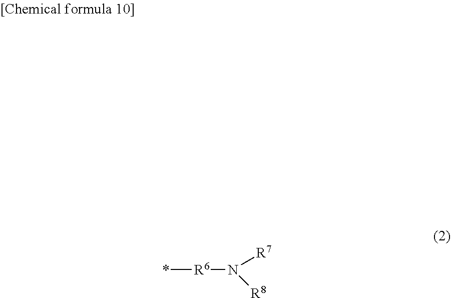

(In Formula (2), R⁶ represents a divalent organic group having a carbon number of 1 or more, R⁷ and R⁸ are each independently a hydrogen atom or a monovalent organic group having a carbon number of 1 or more, and * represents a bond.)

In the abrasive grains according to the second example, by further introducing the alkyl group to the surface, the number of silanol groups on the surface can be reduced to become hydrophobic, and the interaction with the silicon oxide film can be reduced. Accordingly, the polishing rate ratio of the silicon oxide film with respect to the tungsten film can be reduced. Thus, the tungsten film can be further selectively polished.

The production methods and the properties of the abrasive grains according to the first example and the second example have been described above and therefore the description will be omitted.

When the total mass of the composition for chemical mechanical polishing is set to be 100 mass %, the content of the abrasive grains is preferably 1 mass % or more, more preferably 2 mass % or more, and particularly preferably 3 mass % or more. When the total mass of the composition for chemical mechanical polishing is set to be 100 mass %, the content of the abrasive grains is preferably 10 mass % or less, more preferably 8 mass % or less, and particularly preferably 6 mass % or less. When the content of the abrasive grains is in the above range, high-speed polishing with respect to the tungsten film as the polishing target can be realized, and the storage stability of the composition for chemical mechanical polishing becomes preferable.

### 2.2. Liquid Medium

The composition for chemical mechanical according to the embodiment polishing contains a liquid medium. As the liquid medium, examples may include water, mixed media of water and alcohol, mixed media containing water and organic solvents compatible with water, etc. Among the above, water and a mixed medium of water and alcohol are preferably used, and water is more preferably used. The water is not particularly limited, but pure water is preferred. It suffices as long as water is added as the remainder of the constituent materials of the composition for chemical mechanical polishing, and the content of water is not particularly limited.

### 2.3. Other Additives

The composition for chemical mechanical polishing according to the embodiment may, as needed, contain an acidic compound, an iron (III) compound, an oxidization agent, a water-soluble polymer, a surfactant, a corrosion resistant, a PH adjuster, etc. In the case where the polishing target of the composition for chemical mechanical polishing according to the embodiment is set as a tungsten film, it is preferable to contain an acidic compound, an iron compound, and an oxidization agent. In the following, the respective additives are described.

### <Acidic Compound>

The composition for chemical mechanical polishing according to the embodiment may also contain an acidic compound. With the acidic compound, the polishing rate of the tungsten film can be facilitated due to the synergistic effect with the abrasive grains.

As such acidic compound, examples may include organic and inorganic acids. Examples as organic acids may include, for example, saturated carboxylic acids such as malonic acid, citric acid, malic acid, tartaric acid, oxalic acid, lactic acid, and iminodiacetic acid; unsaturated monocarboxylic acids such as acrylic acid, methacrylic acid, crotonic acid, 2-butenoic acid, 2-methyl-3-butenoic acid, 2-hexenoic acid, and 3-methyl-2-hexenoic acid; unsaturated dicarboxylic acids such as maleic acid, fumaric acid, citraconic acid, mesaconic acid, 2-pentenedioic acid, itaconic acid, allylmalonic acid, isopropylidenesuccinic acid, 2,4-hexadienedioic acid, and acetylenedicarboxylic acid; and aromatic carboxylic acids such as trimellitic acid, and the salts thereof. As inorganic acids, example may include, phosphoric acid, sulfuric acid, hydrochloric acid, nitric acid, and the salts thereof, for example. One type of the acidic compounds may be used alone, or two or more types of the acidic compounds may be used together.

In the case where the composition for chemical mechanical polishing according to the embodiment contains the acidic compound, if the total mass of the composition for chemical mechanical polishing is 100 mass %, the content of the acidic compound is preferably 0.001 mass % to 5 mass %, more preferably 0.002 mass % to 1 mass %, and particularly preferably 0.003 mass % to 0.5 mass %.

### <Iron (III) Compound>

The composition for chemical mechanical polishing according to the embodiment may also contain an iron (III) compound. With the iron (III) compound, the tungsten surface is oxidized and a fragile modified layer is created on the tungsten surface, and the polishing rate of the tungsten film can be facilitated.

As the iron (III) compound, any one of organic and inorganic acid ferric salts may be selected. Specific examples of the iron (III) compound may include iron (III) nitrate, ammonium iron (III) sulfate, iron (III) perchlorate, iron (III) chloride, iron (III) sulfate, iron (III) citrate, ammonium iron (III) citrate, and ammonium iron (III) oxalate, etc. Among the iron (III) compounds, iron (III) nitrate is particularly preferred. One type of the iron (III) compounds may be used alone, or two or more types of the iron (III) compounds may be used together.

In the case where the composition for chemical mechanical polishing according to the embodiment contains the iron (III) compound, if the total mass of the composition for chemical mechanical polishing is 100 mass %, the content of the iron (III) compound is preferably 0.001 mass % to 1 mass %, more preferably 0.002 mass % to 0.5 mass %, and particularly preferably 0.003 mass % to 0.3 mass %.

### <Oxidization Agent>

The composition for chemical mechanical polishing according to the embodiment may also contain an oxidization agent. With the oxidization agent, the tungsten film can be oxidized and a fragile modified layer is created by oxidizing the tungsten film. Therefore, the polishing rate may be facilitated.

As the oxidization agent, examples may include ammonium persulfates, potassium persulfates, hydrogen peroxides, cerium diammonium nitrates, potassium hypochlorites, ozone, potassium periodates, peracetic acids, etc. Considering the oxidization power and ease of handling, among the oxidization agents, ammonium persulfate, potassium persulfate, hydrogen peroxide are preferred, and hydrogen peroxide is more preferred. One type of the oxidization agents may be used alone, or two or more types of the oxidization agents may be used together.

In the case where the composition for chemical mechanical polishing according to the embodiment contains the oxidization agent, if the total mass of the composition for chemical mechanical polishing is 100 mass %, the content of the oxidization agent is preferably 0.1 mass % to 5 mass %, more preferably 0.3 mass % to 4 mass %, and particularly preferably 0.5 mass % to 3 mass %. Since the oxidization agent is easily decomposed in the composition for chemical mechanical polishing, the oxidization agent may be added immediately before the CMP polishing process is performed.

### <Water-Soluble Polymer>

The composition for chemical mechanical polishing according to the embodiment may also contain a water-soluble polymer. The water-soluble polymer has the effect of reducing polishing friction by being adsorbed to the polished surface. With the effect, the occurrence of dishing on the polished surface can be reduced.

As the water-soluble polymer, examples may include polymeric amine compounds, such as polyethylenimine, poly(meth)acrylamide, poly(N-alkyl(meth)acrylamide), poly(meth)acrylic acid, polyoxyethylene alkylamine, polyvinyl alcohol, polyvinyl alkyl ether, polyvinylpyrrolidone, hydroxyethyl cellulose, carboxymethyl cellulose, a copolymer of (meth)acrylic acid and maleic acid, poly(meth)acrylamine, etc. Among the above, by adding thermoresponsive polymers such as polyvinyl methyl ether and poly(N-isopropylacrylamide) or polymeric amine compounds such as poly(meth)acrylamine, the occurrence of dishing on the polished surface can be effectively reduced without reducing the polishing rate with respect to the polished surface.

The weight average molecular weight (Mw) of the water-soluble polymer is preferably 1,000 to 1,000,000, and more preferably 3,000 to 800,000. When the weight average molecular weight (Mw) of the water-soluble polymer is in the range, the absorption to the polished surface becomes easy, and the polishing friction can be further reduced. As a result, the occurrence of dishing on the polished surface can be effectively reduced. The “weight average molecular weight (MW)” in the specification refers to the weight average molecular weight through polyethylene glycol conversion as measured by gel permeation chromatography (GPC).

In the case where the composition for chemical mechanical polishing according to the embodiment contains the water-soluble polymer, if the total mass of the composition for chemical mechanical polishing is 100 mass %, the content of the water-soluble polymer is preferably 0.005 mass % to 0.5 mass %, and more preferably 0.01 mass % to 0.2 mass %.

While the content of the water-soluble polymer depends on the weight-average molecular weight (Mw) of the water-soluble polymer, the content of the water-soluble polymer is preferably adjusted so that the viscosity of the composition for chemical mechanical polishing at 25° C. is 0.5 mPa·s or more and less than 10 mPa·s. When the viscosity of the composition for chemical mechanical polishing at 25° C. is 0.5 mPa·s or more and less than 10 mPa·s, the polished surface can be polished at a high speed, and the composition for chemical mechanical polishing can be stably supplied onto a polishing cloth, as the viscosity is appropriate.

### <Surfactant>

The composition for chemical mechanical polishing according to the embodiment may also contain a surfactant. With the surfactant, the composition for chemical mechanical polishing can be imparted with suitable viscosity. The viscosity of the composition for chemical mechanical polishing is preferably adjusted to be 0.5 mPa·s or more and less than 10 mPa·s at 25° C.

The surfactant is not particularly limited, and examples may include anionic surfactants, cationic surfactants, nonionic surfactants, etc.

As the anionic surfactant, examples may include: carboxylates such as fatty acid soaps and alkyl ether carboxylates; sulfonates such as alkylbenzenesulfonate, alkylnaphthalenesulfonate, α-olefinsulfonate; sulfate such as higher alcohol sulfates, alkyl ether sulfates, polyoxyethylene alkyl phenyl ether sulfates; and fluorine-containing surfactants such as perfluoroalkyl compounds. As the cationic surfactant, examples may include aliphatic amine salts, aliphatic ammonium salts, etc. As the nonionic surfactant, examples may include nonionic surfactants with triple bonds such as acetylene glycol, acetylene glycol ethylene oxide adducts, and acetylene alcohol, and polyethylene glycol surfactants. One type of the surfactants may be used alone, or two or more types of the surfactants may be used together.

In the case where the composition for chemical mechanical polishing according to the embodiment contains the surfactant, if the total mass of the composition for chemical mechanical polishing is 100 mass %, the content of the surfactant is preferably 0.001 mass % to 5 mass %, more preferably 0.003 mass % to 3 mass %, and particularly preferably 0.005 mass % to 1 mass %.

### <Corrosion Resistant>

The composition for chemical mechanical polishing according to the embodiment may also contain a corrosion resistant. As the corrosion resistant, examples may include benzotriazole and its derivatives. The benzotriazole derivatives refer to benzotriazole in which one or more hydrogen atoms have been substituted with, for example, a carboxy group, a methyl group, an amino group, a hydroxyl group, etc. Specific examples of the benzotriazole derivatives may include 4-carboxybenzotriazole, 7-carboxybenzotriazole, benzotriazole butyl ester, 1-hydroxymethylbenzotriazole, 1-hydroxybenzotriazole, and salts thereof.

In the case where the composition for chemical mechanical polishing according to the embodiment contains the corrosion resistant, if the total mass of the composition for chemical mechanical polishing is 100 mass %, the content of the corrosion resistant is preferably 1 mass % or less, and more preferably 0.001 mass % to 0.1 mass %.

### <pH Modifier>

The composition for chemical mechanical polishing according to the embodiment may, as needed, further contain a pH modifier. As the pH modifier, examples may include acids such as hydrochloric acids, nitric acids, sulfuric acids, phosphoric acids; and bases such as potassium hydroxide, ethylenediamine, monoethanolamine, tetramethylammonium hydroxide (TMAH), tetraethylammonium hydroxide (TEAH), ammonia.

2.4 pH

The pH of the composition for chemical mechanical polishing according to the embodiment is preferably 2 or more and 5 or less, and more preferably 2 or more and 4 or less. In the region in which the pH of the composition for chemical mechanical polishing is 2 or more and 5 or less, the tungsten surface is easily changed into an oxide that is easily removed mechanically. Therefore, high-speed polishing with respect to the tungsten film can be realized. In addition, when pH of the composition for chemical mechanical polishing is 2 or more and 5 or less, by facilitating the dispersibility of the abrasive grains, the storage stability of the composition for chemical mechanical polishing is favorable and thus preferable.

The pH of the composition for chemical mechanical polishing according to the embodiment can be adjusted by appropriately increasing or decreasing the content of the acidic compound or the pH modifier, etc.

In the specification, pH refers to the hydrogen-ion exponent, and the value thereof can be measured by using a commercially available pH meter (e.g., a desktop pH meter manufactured by Horiba, Ltd.) under the conditions of 25° C. and one atmospheric pressure.

### 2.5 Purpose

According to an aspect of the composition for chemical mechanical polishing according to an embodiment, the composition can be used as a polishing material for selectively polishing the tungsten film among multiple materials forming the semiconductor device. Such composition for chemical mechanical polishing is particularly suitable for the purpose of polishing a redundant tungsten film on an insulation film (e.g., silicon oxide film), and can be used at the time of producing a contact hole for electrically bonding the wires in the upper-lower vertical direction. In addition, according to an aspect of the composition for chemical mechanical polishing, the composition can be used as a polishing material for polishing the silicon oxide film at a high speed.

### 2.6 Method for Preparing Composition for Chemical Mechanical Polishing

The composition for chemical mechanical polishing according to the embodiment can be prepared by dissolving or dispersing the respective components in the liquid medium, such as water. The method for dissolving or dispersion is not particularly limited, and any method may be applied as long as the composition can be uniformly dissolved or dispersed. In addition, the mixing order or the mixing method of the respective components are not particularly limited.

In addition, the composition for chemical mechanical polishing according to the embodiment is prepared as a concentrated stock solution, and can be used by being diluted by using a liquid media, such as water, at the time of being used.

### 3. POLISHING METHOD

An aspect of the polishing method according to the invention includes a process of polishing the silicon oxide film by using the composition for chemical mechanical polishing. With the composition for chemical mechanical polishing, the silicon oxide film can be polished at a high speed.

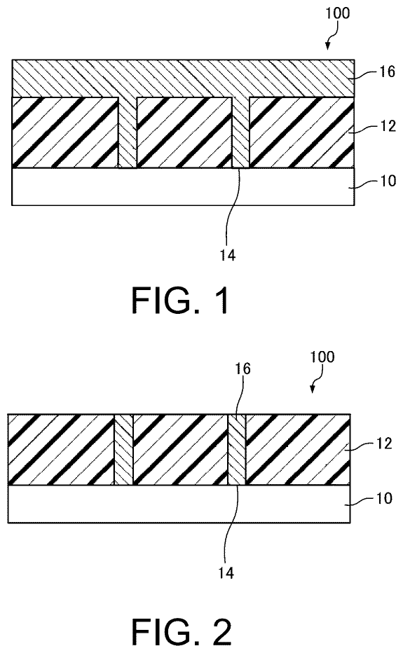

In addition, an aspect of the polishing method according to the invention includes a process of selectively polishing the tungsten film by using the composition for chemical mechanical polishing. With the composition for chemical mechanical polishing, the tungsten film can be selectively polished, so a tungsten plug with favorable quality can be formed. In the following, the polishing method (production of a tungsten plug) according to the embodiment will be described in detail with reference to FIGS. 1 to 3.

### 3.1. Processed Workpiece

FIG. 1 illustrates an example of a processed workpiece 100 suitable for the polishing method according to the embodiment.
(1) Firstly, as shown in FIG. 1, a substrate 10 is prepared. The substrate 10, for example, may be formed by a silicon substrate and a silicon oxide film formed on the silicon substrate. In addition, a functional device, such as a transistor, may be formed on the substrate 10.
(2) Then, on the substrate 10, through a CVD process using silane gas and oxygen gas, a silicon oxide film 12 that is an insulation film is formed. Then, through CMP, the silicon oxide film 12 is polished until halfway to planarize the surface.
(3) Then, a resist pattern is formed on the silicon oxide film 12. By using the resist pattern as the mask, the silicon oxide film 12 is etched, and a contact hole 14 is formed. After the contact hole 14 is formed, the resist pattern is removed.
(4) Then, by performing CVD, a tungsten film 16 is stacked on the surface of the silicon oxide film 12 and in the contact hole 14.

Through the processes, the processed workpiece 100 is formed.

### 3.2. Polishing Process

In the polishing process, as shown in FIG. 2, the composition for chemical mechanical polishing is used to polish the tungsten film 16 until the silicon oxide film 12 is exposed. With the composition for chemical mechanical polishing, the polishing rate of the tungsten film can be increased, and the tungsten film can be selectively polished. Therefore, a tungsten plug with favorable quality can be formed.

After the polishing process, it is preferable to remove the abrasive grains remaining on the polished surface. The abrasive grains can be removed by performing a conventional cleaning process. For example, the abrasive grains attached to the polished surface can be removed by performing cleaning with a basic cleaning solution of ammonia, hydrogen peroxide, and water in a ratio of about 1:1:5 (mass ratio), after brush scrub cleaning is performed. In addition, as a cleaning solution for impurity metal species adsorbed on the polished surface, for example, citric acid solutions, mixed solutions of hydrofluoric acid and citric acid, mixed solutions of hydrofluoric acid and ethylenediaminetetraacetic acid (EDTA), etc., can be used.

### 3.3. Chemical Mechanical Polishing Device

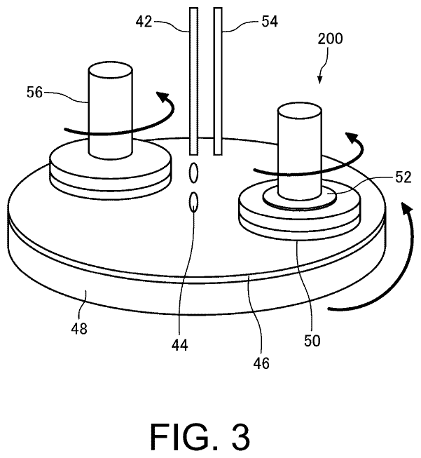

In the polishing process, for example, a chemical mechanical polishing device 200 can be used as shown in FIG. 3. FIG. 3 is a schematic perspective view illustrating the chemical mechanical polishing device 200. A slurry (composition for chemical mechanical polishing) 44 is supplied from a slurry supply nozzle 42, and a turntable 48 to which a polishing pad 46 is adhered is rotated, while a carrier head 52 holding a semiconductor substrate 50 is brought into contact. In FIG. 3, a water supply nozzle 54 and a dresser 56 are shown together.

The polishing load of the carrier head 52 can be selected within a range of 10 hPa to 980 hPa, and is preferably 30 hPa to 490 hPa. The rotation speeds of the turntable 48 and the carrier head 52 can be appropriately selected within the range of 10 rpm to 400 rpm, and are preferably from 30 rpm to 150 rpm. The flow rate of the slurry 44 (composition for chemical mechanical polishing) supplied from the slurry supply nozzle 42 can be selected within the range of 10 mL/min to 1,000 mL/min, and is preferably 50 mL/min to 400 mL/min.

Examples of commercially available chemical mechanical polishing devices may include: models “EPO-112” and “EPO-222” manufactured by Ebara Corporation; models “LGP-510” and “LGP-552” manufactured by Lapmaster SFT; models “Mirra” and “Reflexion” manufactured by Applied Materials, Inc.; model “POLI-400L” manufactured by G&P Technology; model number “Reflexion LK” manufactured by AMAT.

### 4. EXAMPLES

In the following, the invention is described with the examples, and the invention shall not be limited by the examples. In the examples, “parts” and “%” are by mass unless otherwise specified.

### 4.1 Production of Abrasive Grains

### 4.1.1 Synthesis of Silica Particle A

Under room temperature and normal pressure, 100 parts by mass of tetramethyl orthosilicate (manufactured by Tama Chemicals Co., Ltd.) and 26.8 parts by mass of methanol were mixed to produce a monomer solution. Then, 61.2 parts by mass of an aqueous ammonia solution (28 mass %), 98.6 parts by mass of water, and 791.4 parts by mass of methanol were charged into a reaction vessel, and the monomer solution prepared above was gradually poured in over 30 minutes while being stirred at 35° C. In addition, the solution was heated to 90° C. for 6 hours. Then, 341 parts by mass of water was added, and the reaction liquid was concentrated under reduced pressure to prepare a dispersion of silica particles A having a silica equivalent concentration of 20 mass %.

### 4 1.2. Synthesis of Silica Particle B

Under room temperature and normal pressure, while stirring 1,216 parts by mass of water, 100 parts by mass of tetramethyl orthosilicate (manufactured by Tama Chemicals Co., Ltd.) was added and reacted for 1 hour to prepare a hydrolyzed liquid of tetramethyl orthosilicate. Then, while stirring a mixture liquid of 0.2 parts by mass of tetramethylammonium hydroxide (IN aqueous solution manufactured by FUJIFILM Wako Pure Chemical Industries) and 1737 parts by mass of water heated to 80° C., the previously prepared hydrolyzed solution of tetramethyl orthosilicate was fully added at a rate of 6 mL/min. When the pH of the solution drops to 6.35 during the process of addition, the IN aqueous solution of tetramethylammonium hydroxide was successively added to adjust the reaction solution to about pH 8. After the addition was completed, the filtration through a 90-μm mesh filter was performed, and then concentration under reduced pressure was performed. A dispersion of silica particles B in which the particles were linked together like beads and which had a silica equivalent concentration of 20 mass % was prepared.

### 4.2 Example 1

### 4.2.1 Preparation of Abrasive Grains

In 100 parts by mass of the dispersion of the silica particles A prepared above, 0.14 parts by mass of 3-glycidoxypropyltrimethoxysilane as the alkoxysilane having the epoxy group was dropped in while the dispersion was being stirred, and the dispersion was stirred for two hours after being heated to 60° C. Then, 9.21 parts by mass of a 5% aqueous ammonia solution as the basic compound was added while being stirred, and was heated for two hours at 60° C., so that the group represented in Formula (4) below was immobilized on the surface of the silica particle A.

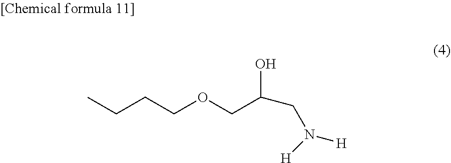

(In Formula (4), * represents a bond)
In addition, after being concentrated to 90 parts by mass under the reduced pressure condition of 60° C. and 100 hPa, ultrapure water was added to prepare an abrasive grain dispersion containing 20 mass % of abrasive grains having the groups represented in Formula (4) immobilized onto the surfaces of the silica particles A.

### 4.2.2 Preparation of Composition for Chemical Mechanical Polishing

### <Preparation of Composition A for Chemical Mechanical Polishing>

Malonic acid, iron (III) nitrate, and water were added to the abrasive grain dispersion prepared above, and were mixed so that the malonic acid was 0.0028 mass % and the iron (III) nitrate was 0.036 mass %, and then 1% of nitric acid was added to adjust pH to 2.5. Then, 35 mass % of an aqueous hydrogen peroxide solution (produced by Fujifilm Wako Pure Chemical Industries, Ltd.) was added so that hydrogen peroxide was 1 mass %, and filtration was performed by using a filter with a pore diameter of 0.3 μm to prepare the composition A for chemical mechanical polishing.

### <Preparation of Composition B for Chemical Mechanical Polishing>

Water was added to the abrasive grain dispersion prepared above and mixed so that the abrasive grains became 1 mass %, and then 1% of nitric acid was added to adjust pH to 4.5. Then, by performing filtration using a filter with a pore diameter of 0.3 μm, the composition B for chemical mechanical polishing was prepared.

4.2.3 Evaluation method

### <Measurement of Zeta Potential of Abrasive Grains>

The zeta potential (surface charge) of the abrasive grains containing the respective compositions for chemical mechanical polishing produced according to the above were measured by using the ultrasonic particle size distribution-zeta potential measurement device (“DT-300” manufactured by Dispersion Technology). The results are as shown in Table 1 below.

### <Measurement of Average Secondary Particle Size of Abrasive Grains>

The average secondary particle size of the abrasive grains containing the respective compositions for chemical mechanical polishing produced according to the above were measured by using the nano-particle analysis device SZ-100 manufactured by Horiba, Ltd. The results are as shown in Table 1 below.

### <Evaluation on Polishing Rate>

The composition A for chemical mechanical polishing prepared above was used, a 12-inch silicon substrate with a tungsten film of 600 nm and a 12-inch silicon substrate with a silicon oxide film of 2000 nm were respectively used as polished workpieces, and chemical mechanical polishing was performed under the following conditions by using a chemical mechanical polishing device (model “POLI-400L” manufactured by G&P Technology). The results are as shown in Table 1 below.

In addition, the composition B for chemical mechanical polishing prepared above was used, a 12-inch silicon substrate with a silicon oxide film of 2000 nm was used as a polished workpiece, and chemical mechanical polishing was performed under the following conditions by using the chemical mechanical polishing device (model “POLI-400L” manufactured by G&P Technology). The results are as shown in Table 1 below.

Regarding the thickness of the tungsten film before and after polishing, the resistance was measured through a DC four-probe method by using a resistance rate measurement machine (model “Σ-5” manufactured by NPS), and the thickness was calculated from the sheet resistance and a volume resistance rate of tungsten according to the following equation.

Film thickness (Å)=[Volume resistance rate of tungsten film (Ω·m)÷sheet resistance (Ω)]×10¹⁰

Regarding the thickness of the silicon oxide film before and after polishing, the thickness was measured by using a contactless optical film thickness measurement device (“NanoSpec 6100” manufactured by Nanometrics Japan).

### (Polishing Conditions)

Polishing pad: Model No. “IC1000” manufactured by Nitta DuPont
Carrier head load: 129/cm²
Surface plate rotation speed rpm: 100 rpm
Polishing head rotation speed: 90 rpm
Supply amount of the composition for chemical mechanical polishing: 50 mL/min

### (Evaluation Criteria Relating to Composition a for Chemical Mechanical Polishing)

In the case where the polishing rate ratio of the silicon oxide film with respect to the tungsten film is 10 or more, the tungsten film can be selectively polished, so it is determined as favorable.

### (Evaluation Criteria Relating to Composition B for Chemical Mechanical Polishing)

In the case where the polishing rate of the silicon oxide film is 1500 Å or more, the polishing rate is determined as sufficiently fast and favorable.

### <Evaluation on Storage Stability>

After being prepared, the compositions for chemical mechanical polishing were left to stand at 60° C. and normal pressure. After being left to stand for a week, the respective compositions for chemical mechanical polishing were observed visually to evaluate storage stability. As an index for evaluating storage stability, by using the dynamic light scattering particle size measurement device, the average particle sizes of the abrasive grains immediately after preparation and after one week of standing were obtained as arithmetic average sizes, and the storage stability was evaluated from the change of the average particle sizes. The evaluation criteria are as follows. The results are as shown in Table 1 below.

### (Evaluation Criteria)

In the case where the change of the average particle size of the abrasive grains between immediately after the preparation and after one week of standing is less than 5 nm, it can be estimated that stable polishing properties are found for a long time, so the abrasive grains are determined as very favorable and labeled as “AA”.
In the case where the change of the average particle size of the abrasive grains between immediately after the preparation and after one week of standing is 5 nm and less than 10 nm, it can be determined that, while long-term storage is not possible, there is no problem with commercial use within a short term from production to use, so the abrasive grains are determined as favorable and labeled as “A”.
In the case where the change of the average particle size of the abrasive grains between immediately after the preparation and after one week of standing is equal to or more than 10 nm or the abrasive grains agglomerate and settle, the abrasive grains cannot be supplied for actual use and are therefore determined as poor and labeled as “B”.

### 4.3 Examples 2 to 13

In “4.2.1 Preparation of abrasive grains” of Example 1, the silica particles, the silane compounds having the epoxy groups, and the basic compounds were set as the types and the addition amounts as shown in Tables 1 and 2 below. Except to the above, the abrasive grains were produced like Example 1, and the compositions for chemical mechanical polishing were prepared. Then, the prepared compositions for chemical mechanical polishing were evaluated like Example 1. The results are as shown in Tables 1 and 2 below.

The abrasive grains used in Examples 2 to 6 and 13 are abrasive grains having the groups represented in Formula (4) like Example 1 on the surfaces. The abrasive grains used in Example 7 are abrasive grains having the groups represented in Formula (5) on the surfaces. The abrasive grains used in Example 8 are abrasive grains having the groups represented in Formula (6) on the surfaces. The abrasive grains used in Example 9 are abrasive grains having the groups represented in Formula (7) on the surfaces. The abrasive grains used in Example 10 are abrasive grains having the groups represented in Formula (8) on the surfaces. The abrasive grains used in Example 11 are abrasive grains having the groups represented in Formula (9) on the surfaces. The abrasive grains used in Example 12 are abrasive grains having the groups represented in Formula (10) on the surfaces. In Formulae (5) to (10), * represents a bond.

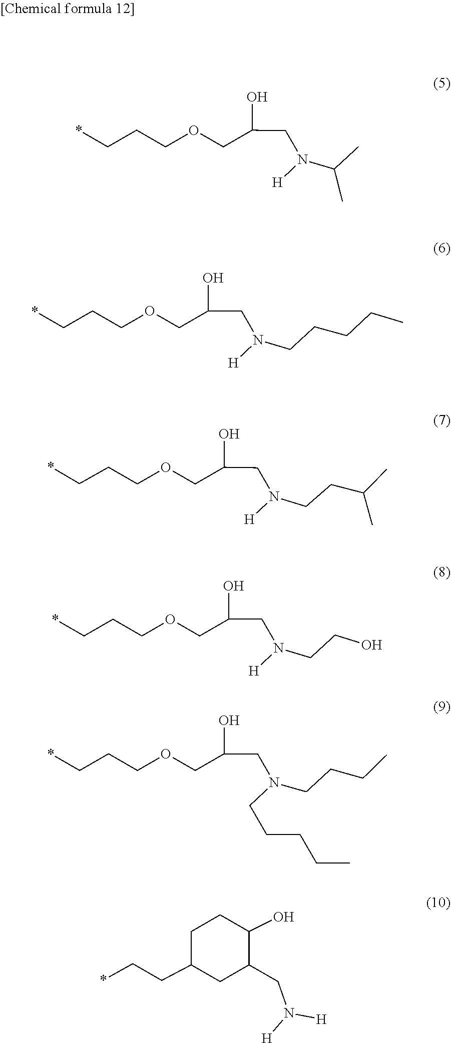 [SMILES: *CCCOCC(O)CNC(C)C ; *CCCOCC(O)CNCCCCC ; *CCCOCC(O)CNCCC(C)C ; *CCCOCC(O)CNCCO ; *CCCOCC(O)CN(CCCC)CCCCC ; *CCC1CCC(O)C(CN)C1]

### 4.4 Example 14

In 100 parts by mass of the dispersion of the silica particles A prepared above, 0.14 parts by mass of 3-glycidoxypropyltrimethoxysilane as the silane compound having the epoxy group was 5 dripped while being stirred, 9.21 parts by mass of a 5% aqueous ammonia solution was further added, and then heating was performed for two hours at 60° C. In addition, after being concentrated to 90 parts by mass under the reduced pressure condition of 60° C. and 100 hPa, ultrapure water was added to prepare abrasive grain dispersions containing 20 mass % of abrasive grains having the groups represented in Formula (4) immobilized onto the surfaces of the silica particles A on the surface, and the respective compositions for chemical mechanical polishing were prepared. Then, the prepared compositions for chemical mechanical polishing were evaluated like Example 1. The results are as shown in Table 2 below.

### 4.5 Example 15

After abrasive grains were prepared like Example 4, the obtained abrasive grains were further mixed with 0.14 parts by mass of methyltrimethoxysilane as the silane compound having the alkyl group, and the mixture was heated at 60° C. for 2 hours. Then, after being concentrated to 90 parts by mass under the reduced pressure condition of 60° C. and 100 hPa, ultrapure water was added to prepare an abrasive grain dispersion containing 20 mass % of abrasive grains having the methyl groups and the groups represented in Formula (4) on the surfaces of the silica particles B on the surface. Then, the composition A for chemical mechanical polishing was prepared like Example 4, and evaluation was made like Example 4. The results are as shown in Table 3 below. In Example 15, the composition B for chemical mechanical polishing was not prepared, and the evaluation of the silicon oxide film was not carried out.

### 4. 6 Examples 16 to 20

In Example 15, the silane compounds having the alkyl groups were set with the types and the addition amounts as shown in Table 3 below. Except to the above, the abrasive grains were produced like Example 15, and the composition A for chemical mechanical polishing was prepared. Then, the prepared composition A for chemical mechanical polishing was evaluated like Example 15. The results are as shown in Table 3 below.

### 4.7 Example 21

In 100 parts by mass of the dispersion of the silica particles B prepared above, 0.14 parts by mass of 3-glycidoxypropyltrimethoxysilane as the silane compound having the epoxy group and 0.14 parts by mass of methyltrimethoxysilane as the silane compound having the alkyl group were dripped while being stirred, 9.21 parts by mass of a 5% aqueous ammonia solution was added and then heating was performed for two hours at 60° C. In addition, after being concentrated to 90 parts by mass under the reduced pressure condition of 60° C. and 100 hPa, ultrapure water was added to prepare an abrasive grain dispersion containing 20 mass % of abrasive grains having the methyl groups and the groups represented in Formula (4) on the surfaces of the silica particles B on the surface. Then, the composition A for chemical mechanical polishing was prepared like Example 15, and evaluation was made like Example 15. The results are as shown in Table 3 below.

### 4.8 Comparative Examples 1 and 2

Except that the silica particles A (Comparative Example 1) and silica particles B (Comparative Example 2) on which particle surfaces were not modified were directly adopted as abrasive particles, the compositions for chemical mechanical polishing like Example 1 were prepared and evaluated. The results are as shown in Table 2 below.

### 4.9 Evaluation Results

In Tables 1 to 3, the reagents and addition amounts used in the production process of the abrasive grains in the respective examples and comparative examples, as well as the respective evaluation results of the compositions for chemical mechanical polishing are shown. In the respective tables, “Composition A” refers to the composition A for chemical mechanical polishing as prepared above, and “Composition B” refers to the composition B for chemical mechanical polishing as prepared above.

TABLE 1

| | | | Example 1 | Example 2 | Example 3 | Example 4 |
|---|---|---|---|---|---|---|
| ABRASIVE | Silicon | Type | A | A | A | B |
| GRAINS | dioxide | Added | 100 | 100 | 100 | 100 |
| | particles | amount | | | | |
| | | (parts by | | | | |
| | | mass) | | | | |
| | Silane | Type | 3- | 3- | 3- | 3- |
| | compound | | Glycidoxypropyltri- | Glycidoxypropyltri- | Glycidoxypropyltri- | Glycidoxypropyltri- |
| | having an | | methoxysilane | methoxysilane | methoxysilane | methoxysilane |
| | epoxy group | Added | 0.14 | 0.28 | 0.42 | 0.14 |
| | | amount | | | | |
| | | (parts by | | | | |
| | | mass) | | | | |
| | Basic | Type | Ammonia | Ammonia | Ammonia | Ammonia |
| | compound | | (5% aqueous | (5% aqueous | (5% aqueous | (5% aqueous |
| | | | solution) | solution) | solution) | solution) |
| | | Added | 9.21 | 18.42 | 27.63 | 9.21 |
| | | amount | | | | |
| | | (parts by | | | | |
| | | mass) | | | | |
| Composition A | Zeta potential of | | 22 | 28 | 35 | 24 |
| | abrasive grains (mV) | | | | | |
| | Average secondary | | 51 | 52 | 51 | 53 |
| | particle size of abrasive | | | | | |
| | grains (nm) | | | | | |
| | pH | | 2.5 | 2.5 | 2.5 | 2.5 |
| Composition B | Zeta potential of | | 11.8 | 17.4 | 22.9 | 12.4 |
| | abrasive grains (mV) | | | | | |
| | Average secondary | | 51 | 51 | 51 | 53 |
| | particle size of abrasive | | | | | |
| | grains (nm) | | | | | |
| | pH | | 4.5 | 4.5 | 4.5 | 4.5 |
| Evaluation of | Polishing | Tungsten | 1804 | 1950 | 2120 | 2010 |
| Composition A | rate | film (Å/min) | | | | |
| | | Silicon oxide | 68 | 54 | 34 | 77 |
| | | film (Å/min) | | | | |
| | Polishing | Tungsten | 26.5 | 36.1 | 62.4 | 26.1 |
| | rate ratio | film (Å/min)/ | | | | |
| | | Silicon | | | | |
| | | oxide film | | | | |
| | | (Å/min) | | | | |
| | Storage stability | | A | AA | AA | A |
| Evaluation of | Polishing | Silicon oxide | 2440 | 2281 | 1775 | 2894 |
| Composition B | rate | film (Å/min) | | | | |
| | Storage stability | | A | AA | AA | A |
| | | | Example 5 | Example 6 | Example 7 | Example 8 |
| ABRASIVE | Silicon | Type | B | B | B | B |
| GRAINS | dioxide | Added | 100 | 100 | 100 | 100 |
| | particles | amount | | | | |
| | | (parts by | | | | |
| | | mass) | | | | |
| | Silane | Type | 3- | 3- | 3- | 3- |
| | compound | | Glycidoxypropyltri- | Glycidoxypropyltri- | Glycidoxypropyltri- | Glycidoxypropyltri- |
| | having an | | methoxysilane | methoxysilane | methoxysilane | methoxysilane |
| | epoxy group | Added | 0.28 | 0.42 | 0.14 | 0.14 |
| | | amount | | | | |
| | | (parts by | | | | |
| | | mass) | | | | |
| | Basic | Type | Ammonia | Ammonia | Isopropylamine | Pentylamine |
| | compound | | (5% aqueous | (5% aqueous | | |
| | | | solution) | solution) | | |
| | | Added | 18.42 | 27.63 | 3.85 | 5.68 |
| | | amount | | | | |
| | | (parts by | | | | |
| | | mass) | | | | |
| Composition A | Zeta potential of | | 29 | 34 | 22 | 23 |
| | abrasive grains (mV) | | | | | |
| | Average secondary | | 53 | 53 | 53 | 53 |
| | particle size of abrasive | | | | | |
| | grains (nm) | | | | | |
| | pH | | 2.5 | 2.5 | 2.5 | 2.5 |
| Composition B | Zeta potential of | | 18.9 | 23.3 | 12.9 | 12.5 |
| | abrasive grains (mV) | | | | | |
| | Average secondary | | 53 | 53 | 53 | 53 |
| | particle size of abrasive | | | | | |
| | grains (nm) | | | | | |
| | pH | | 4.5 | 4.5 | 4.5 | 4.5 |
| Evaluation of | Polishing | Tungsten | 2120 | 2240 | 2221 | 2195 |
| Composition A | rate | film (Å/min) | | | | |
| | | Silicon oxide | 65 | 56 | 44 | 36 |
| | | film (Å/min) | | | | |
| | Polishing | Tungsten | 32.6 | 40.0 | 50.5 | 61.0 |
| | rate ratio | film (Å/min)/ | | | | |
| | | Silicon | | | | |
| | | oxide film | | | | |
| | | (Å/min) | | | | |
| | Storage stability | | AA | AA | AA | A |
| Evaluation of | Polishing | Silicon oxide | 2428 | 1985 | 2776 | 2499 |
| Composition B | rate | film (Å/min) | | | | |

| | | | | |
|---|---|---|---|---|
| Storage stability | AA | AA | A | A |

| | | | Example 9 | Example 10 | Example 11 | Example 12 |
|---|---|---|---|---|---|---|
| ABRASIVE | Silicon | Type | B | B | B | B |
| GRAINS | dioxide | Added amount | 100 | 100 | 100 | 100 |
| | particles | (parts by mass) | | | | |
| | Silane | Type | 3- | 3- | 3- | 2-(3,4- |
| | compound | | Glycidoxypropyltri- | Glycidoxypropyltri- | Glycidoxypropyltri- | epoxycyclohexyl)ethyltri- |
| | having | | methoxysilane | methoxysilane | methoxysilane | methoxysilane |
| | an epoxy | Added amount | 0.14 | 0.14 | 0.14 | 0.15 |
| | group | (parts by mass) | | | | |
| | Basic | Type | Isoamylamine | Monoethanolamine | Dibutylamine | Ammonia |
| | compound | | | | | (5% aqueous |
| | | | | | | solution) |
| | | Added amount | 5.68 | 5.42 | 8.42 | 9.06 |
| | | (parts by mass) | | | | |
| Composition A | Zeta potential of abrasive | | 22 | 23 | 22 | 22 |
| | grains (mV) | | | | | |
| | Average secondary | | 53 | 51 | 53 | 51 |
| | particle size of abrasive | | | | | |
| | grains (nm) | | | | | |
| | pH | | 2.5 | 2.5 | 2.5 | 2.5 |
| Composition B | Zeta potential of abrasive | | 12.6 | 12.8 | 12.2 | 11.1 |
| | grains (mV) | | | | | |
| | Average secondary | | 53 | 51 | 53 | 51 |
| | particle size of abrasive | | | | | |
| | grains (nm) | | | | | |
| | pH | | 4.5 | 4.5 | 4.5 | 4.5 |
| Evaluation of | Polishing | Tungsten film | 2223 | 2233 | 2120 | 2095 |
| Composition A | rate | (Å/min) | | | | |
| | | Silicon oxide | 35 | 51 | 30 | 66 |
| | | film (Å/min) | | | | |
| | Polishing | Tungsten film | 63.5 | 43.8 | 70.7 | 31.7 |
| | rate | (Å/min)/ | | | | |
| | ratio | Silicon oxide | | | | |
| | | film (Å/min) | | | | |
| | Storage stability | | A | AA | A | A |
| Evaluation of | Polishing | Silicon oxide | 2389 | 2882 | 2344 | 2665 |
| Composition B | rate | film (Å/min) | | | | |

| | | | | |
|---|---|---|---|---|
| Storage stability | A | AA | A | A |

| | | | | | Comparative | Comparative |
|---|---|---|---|---|---|---|
| | | | Example 13 | Example 14 | Example 1 | Example 2 |
| ABRASIVE | Silicon | Type | B | A | A | B |
| GRAINS | dioxide | Added amount | 100 | 100 | 100 | 100 |
| | particles | (parts by mass) | | | | |
| | Silane | Type | 3- | 3- | — | — |
| | compound | | Glycidoxypropyltri- | Glycidoxypropyltri- | | |
| | having | | methoxysilane | methoxysilane | | |
| | an epoxy | Added amount | 0.14 | 0.14 | — | — |
| | group | (parts by mass) | | | | |
| | Basic | Type | Ammonia | Ammonia | — | — |
| | compound | | (5% aqueous | (5% aqueous | | |
| | | | solution) | solution) | | |
| | | Added amount | 9.79 | 9.21 | — | — |
| | | (parts by mass) | | | | |
| Composition A | Zeta potential of abrasive | | 22 | 22 | 2.5 | 9.1 |
| | grains (mV) | | | | | |
| | Average secondary | | 51 | 51 | 51 | 55 |
| | particle size of abrasive | | | | | |
| | grains (nm) | | | | | |
| | pH | | 2.5 | 2.5 | 2.5 | 2.5 |
| Composition B | Zeta potential of abrasive | | 11.3 | 11.8 | 2.3 | 7.1 |
| | grains (mV) | | | | | |
| | Average secondary | | 52 | 51 | 51 | 54 |
| | particle size of abrasive | | | | | |
| | grains (nm) | | | | | |
| | pH | | 4.5 | 4.5 | 4.5 | 4.5 |
| Evaluation of | Polishing | Tungsten film | 2120 | 1800 | 1580 | 1550 |
| Composition A | rate | (Å/min) | | | | |
| | | Silicon oxide | 69 | 66 | 270 | 340 |
| | | film (Å/min) | | | | |
| | Polishing | Tungsten film | 30.7 | 27.3 | 5.9 | 4.6 |
| | rate | (Å/min)/ | | | | |
| | ratio | Silicon oxide | | | | |
| | | film (Å/min) | | | | |
| | Storage stability | | A | A | B | B |
| Evaluation of | Polishing | Silicon oxide | 2721 | 2432 | 1222 | 1351 |
| Composition B | rate | film (Å/min) | | | | |

| | | | | |
|---|---|---|---|---|
| Storage stability | A | A | B | B |

TABLE 2

| | | | | | | | | | Compar- | Compar- |
|---|---|---|---|---|---|---|---|---|---|---|
| | | | | | | | | | ative | ative |
| | | | | | | | | | Exam- | Exam- |
| | | | Example 9 | Example 10 | Example 11 | Example 12 | Example 13 | Example 14 | ple 1 | ple 2 |
| ABRA- | Silicon | Type | B | B | B | B | B | A | A | B |
| SIVE | dioxide | Added | 100 | 100 | 100 | 100 | 100 | 100 | 100 | 100 |
| GRAINS | particles | amount | | | | | | | | |
| | | (parts by | | | | | | | | |
| | | mass) | | | | | | | | |
| | Silane | Type | 3-Glycidoxy- | 3-Glycidoxy- | 3-Glycidoxy- | 2-(3,4-epoxy- | 3- Glycidoxy- | 3-Glycidoxy- | — | — |
| | compound | | propyltri- | propyltri- | propyltri- | cyclohexyl) | propylmethyl- | propyltri- | | |
| | having an | | methoxy- | hoxysilane | hoxysilane | ethyltrim- | dimethoxy- | methoxy- | | |
| | epoxy | | silane | | | ethoxysilane | silane | silane | | |
| | group | Added | 0.14 | 0.14 | 0.14 | 0.15 | 0.14 | 0.14 | — | — |
| | | amount | | | | | | | | |
| | | (parts by | | | | | | | | |
| | | mass) | | | | | | | | |
| | Basic | Type | Isoamyl- | Monoethanol- | Dibutyl- | Ammonia | Ammonia | Ammonia | — | — |
| | compound | | amine | amine | amine | (5% aqueous | (5% aqueous | (5% aqueous | | |
| | | | | | | solution) | solution) | solution) | | |
| | | Added | 5.68 | 5.42 | 8.42 | 9.06 | 9.79 | 9.21 | — | — |
| | | amount | | | | | | | | |
| | | (parts by | | | | | | | | |
| | | mass) | | | | | | | | |
| Compo- | Zeta potential of | | 22 | 23 | 22 | 22 | 22 | 22 | 2.5 | 9.1 |
| sition | abrasive grains | | | | | | | | | |
| A | (mV) | | | | | | | | | |
| | Average secondary | | 53 | 51 | 53 | 51 | 51 | 51 | 51 | 55 |
| | particle size of | | | | | | | | | |
| | abrasive grains | | | | | | | | | |
| | (nm) | | | | | | | | | |
| | pH | | 2.5 | 2.5 | 2.5 | 2.5 | 2.5 | 2.5 | 2.5 | 2.5 |
| Compo- | Zeta potential of | | 12.6 | 12.8 | 12.2 | 11.1 | 11.3 | 11.8 | 2.3 | 7.1 |
| sition | abrasive grains | | | | | | | | | |
| B | (mV) | | | | | | | | | |
| | Average secondary | | 53 | 51 | 53 | 51 | 52 | 51 | 51 | 54 |
| | particle size of | | | | | | | | | |
| | abrasive grains | | | | | | | | | |
| | (nm) | | | | | | | | | |
| | pH | | 4.5 | 4.5 | 4.5 | 4.5 | 4.5 | 4.5 | 4.5 | 4.5 |
| Evaluation | Polishing | Tungsten | 2223 | 2233 | 2120 | 2095 | 2120 | 1800 | 1580 | 1550 |
| of | rate | film | | | | | | | | |
| Compo- | | (Å/min) | | | | | | | | |
| sition | | Silicon | 35 | 51 | 30 | 66 | 69 | 66 | 270 | 340 |
| A | | oxide | | | | | | | | |
| | | film | | | | | | | | |
| | | (Å/min) | | | | | | | | |
| | Polishing | Tungsten | 63.5 | 43.8 | 70.7 | 31.7 | 30.7 | 27.3 | 5.9 | 4.6 |
| | rate | film | | | | | | | | |
| | ratio | (Å/min)/ | | | | | | | | |
| | | Silicon | | | | | | | | |
| | | oxide | | | | | | | | |
| | | film | | | | | | | | |
| | | (Å/min) | | | | | | | | |
| | Storage stability | | A | AA | A | A | A | A | B | B |
| Evaluation | Polishing | Silicon | 2389 | 2882 | 2344 | 2665 | 2721 | 2432 | 1222 | 1351 |
| of | rate | oxide | | | | | | | | |
| Compo- | | film | | | | | | | | |
| sition | | (Å/min) | | | | | | | | |

| | | | | | | | | | |
|---|---|---|---|---|---|---|---|---|---|
| B | Storage stability | A | AA | A | A | A | A | B | B |

TABLE 3

| | | | Example 15 | Example 16 | Example 17 | Example 18 |
|---|---|---|---|---|---|---|
| ABRASIVE | Silicon | Type | B | B | B | B |
| GRAINS | dioxide | Added amount | 100 | 100 | 100 | 100 |
| | particles | (parts by mass) | | | | |
| | Silane | Type | 3- | 3- | 3- | 3- |
| | compound | | Glycidoxypropyltri- | Glycidoxypropyltri- | Glycidoxypropyltri- | Glycidoxypropyltri- |
| | having an | | methoxysilane | methoxysilane | methoxysilane | methoxysilane |
| | epoxy group | Added amount | 0.14 | 0.14 | 0.14 | 0.14 |
| | | (parts by mass) | | | | |
| | Basic | Type | Ammonia | Ammonia | Ammonia | Ammonia |
| | compound | | (5% aqueous | (5% aqueous | (5% aqueous | (5% aqueous |
| | | | solution) | solution) | solution) | solution) |
| | | Added amount | 9.21 | 9.21 | 9.21 | 9.21 |
| | | (parts by mass) | | | | |
| | Silane | Type | Methyltri- | Methyltri- | Methyltri- | n-butyltri- |
| | compound | | methoxysilane | methoxysilane | methoxysilane | methoxysilane |
| | having an | Added amount | 0.14 | 0.28 | 0.36 | 0.92 |
| | alkyl group | (parts by mass) | | | | |
| Composition A | Zeta potential of abrasive | | 19 | 18 | 17 | 22 |
| | grains (mV) | | | | | |
| | Average secondary particle | | 53 | 53 | 53 | 53 |
| | size of abrasive grains (nm) | | | | | |
| | pH | | 2.5 | 2.5 | 2.5 | 2.5 |
| Evaluation of | Polishing | Tungsten film | 2122 | 2118 | 2110 | 2244 |
| Composition A | rate | (Å/min) | | | | |
| | | Silicon oxide | 44 | 38 | 33 | 46 |
| | | film (Å/min) | | | | |
| | Polishing | Tungsten film | 48.2 | 55.7 | 63.9 | 48.8 |
| | rate ratio | (Å/min)/ | | | | |
| | | Silicon oxide | | | | |
| | | film (Å/min) | | | | |

| | | | | |
|---|---|---|---|---|
| Storage stability | AA | A | A | A |

| | | | Example 19 | Example 20 | Example 21 |
|---|---|---|---|---|---|
| ABRASIVE | Silicon | Type | B | B | B |
| GRAINS | dioxide | Added amount | 100 | 100 | 100 |
| | particles | (parts by mass) | | | |
| | Silane | Type | 3- | 3- | 3- |
| | compound | | Glycidoxypropyltri- | Glycidoxypropyltri- | Glycidoxypropyltri- |
| | having an | | methoxysilane | methoxysilane | methoxysilane |
| | epoxy group | Added amount | 0.14 | 0.14 | 0.14 |
| | | (parts by mass) | | | |
| | Basic | Type | Ammonia | Ammonia | Ammonia |
| | compound | | (5% aqueous | (5% aqueous | (5% aqueous |
| | | | solution) | solution) | solution) |
| | | Added amount | 9.21 | 9.21 | 9.21 |
| | | (parts by mass) | | | |
| | Silane | Type | Cyclohexyltri- | n-octyltri- | Methyltri- |
| | compound | | methoxysilane | methoxysilane | methoxysilane |
| | having an | Added amount | 1.05 | 1.92 | 0.14 |
| | alkyl group | (parts by mass) | | | |
| Composition A | Zeta potential of abrasive | | 21 | 20 | 19 |
| | grains (mV) | | | | |
| | Average secondary particle | | 53 | 53 | 53 |
| | size of abrasive grains (nm) | | | | |
| | pH | | 2.5 | 2.5 | 2.5 |
| Evaluation of | Polishing | Tungsten film | 2233 | 2231 | 2115 |
| Composition A | rate | (Å/min) | | | |
| | | Silicon oxide | 39 | 31 | 43 |
| | | film (Å/min) | | | |
| | Polishing | Tungsten film | 57.3 | 72.0 | 49.2 |
| | rate ratio | (Å/min)/ | | | |
| | | Silicon oxide | | | |
| | | film (Å/min) | | | |

| | | | |
|---|---|---|---|
| Storage stability | A | A | AA |

In the reagents of Tables 1 to 3 above, the commercially available products were used, respectively.

### <Silane Compound Having an Epoxy Group>

3-glycidoxypropyltrimethoxysilane: manufactured by Shin-Etsu Silicones Co., Ltd., product name “KBM-403”
2-(3,4-epoxycyclohexyl)ethyltrimethoxysilane: manufactured by Shin-Etsu Silicones Co., Ltd., product name “KBM-303”
3-glycidoxypropylmethyldimethoxysilane: manufactured by Shin-Etsu Silicones Co., Ltd., product name “KBM-402”

### <Basic Compound>

Ammonia (5% aqueous solution): Mitsubishi Gas Chemical Company, Inc., 29% aqueous solution diluted with ultrapure water to 5% and used
Isopropylamine: manufactured by Tokyo Chemical Industry Co., Ltd.
Amylamine: Tokyo Chemical Industry Co., Ltd.
Isoamylamine: manufactured by Tokyo Chemical Industry Co., Ltd.
Monoethanolamine: Tokyo Chemical Industry Co., Ltd.
Dibutylamine: Tokyo Chemical Industry Co., Ltd.

### <Silane Compound Having an Alkyl Group>

Methyltrimethoxysilane: manufactured by Shin-Etsu Silicones Co., Ltd., product name “KBM-13”
n-Butyltrimethoxysilane: manufactured by Fluorochem Ltd.
Cyclohexyltrimethoxysilane: manufactured by Tokyo Chemical Industry Co., Ltd.
n-Octyltrimethoxysilane: Fluorochem Ltd.

In Examples 1 to 21, the abrasive grains having the group of any one of Formulae (4) to (10) on the surfaces were obtained by mixing and heating the particles having the surfaces to which the hydroxyl groups (—OH) were immobilized via the covalent bonds, the alkoxysilanes having the epoxy groups, and the basic compounds. By using the composition A for chemical mechanical polishing containing the abrasive grains, the acidic compound, the iron (III) compound, and the oxidization agent, the tungsten film can be selectively polished with respect to the silicon oxide film, the polishing properties can be achieved favorably, and the storage stability is excellent.

In particular, the abrasive grains having the group represented by Formula (4) and the alkyl group on the surfaces became hydrophobic by reducing the number of silanol groups on the surfaces, and the interaction with the silicon oxide film can be reduced. Therefore, the tungsten film can be further selectively polished.

In addition, in Examples 1 to 14, by using the composition B for chemical mechanical polishing containing the abrasive grains having the group of any one of Formulae (1) to (14) on the surfaces, the silicon oxide film were able to be polished at a high speed, favorable polishing properties were able to be attained, and storage stability was excellent.

Meanwhile, in Comparative Examples 1 to 2, since the silica particles A or silica particles B without surface modification were directly used as the abrasive grains, the selective polishing properties for the tungsten film was poor in the composition A for chemical mechanical polishing, and the polishing rate for the silicon oxide film in the composition B for chemical mechanical polishing decreased.

From the above results, according to the composition A for chemical mechanical polishing according to the embodiment of the invention, the tungsten film can be selectively polished at a high speed with respect to the silicon film, the polishing properties can be favorable, and the storage stability is excellent. Also, according to the composition B for chemical mechanical polishing according to the invention of the embodiment, the silicon oxide film can be polished at a high speed, the polishing properties can be favorable, and the storage stability is excellent.

The invention is not limited to the above-described embodiment, and various modifications are possible. For example, the invention includes configurations substantially the same as the configurations described in the embodiments (for example, configurations having the same functions, methods, and results, or configurations having the same purpose and effect). The invention also includes configurations in which non-essential parts of the configurations described in the embodiments are replaced. Furthermore, the invention includes configurations that have the same effects as the configurations described in the embodiments or that can achieve the same purpose. Furthermore, the invention includes configurations in which publicly known technology is added to the configurations described in the embodiments.

### REFERENCE SIGNS LIST

10: Substrate; 12: Silicon oxide film; 14: Contact hole; 16: Tungsten film; 42: Slurry supply nozzle; 44: Slurry (composition for chemical mechanical polishing); 46 (Polishing pad); 48: Turntable; 50: Semiconductor substrate; 52: Carrier head; 54: Water supply nozzle; 56: Dresser; 100: Workpiece; 200: Chemical mechanical polishing device.

1. A method for producing abrasive grains, comprising:
a process of mixing and heating:
particles each having a surface to which a hydroxyl group is immobilized via a covalent bond;
an alkoxysilane having an epoxy group; and
a basic compound.

2. The method for producing the abrasive grains as claimed in claim 1, comprising:
a first process of heating a mixture containing the particles each having the surface to which the hydroxyl group is immobilized via the covalent bond and the alkoxysilane having the epoxy group; and
a second process of, after the first process, further adding the basic compound and performing heating.

3. The method for producing the abrasive grains as claimed in claim 2, further comprising a third process of, after the second process, further adding an alkoxysilane having an alkyl group and performing heating.

4. The method for producing the abrasive grains as claimed in claim 1, wherein the basic compound is at least one selected from a group consisting of ammonia and a compound having an amino group.

5. The method for producing the abrasive grains as claimed in claim 1, wherein the abrasive grains are provided with a portion of a structure represented by Formula (1) below on a surface of the abrasive grain, 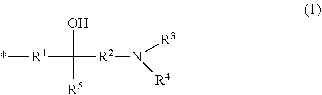
wherein in Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.

6. The method for producing the abrasive grains as claimed in claim 3, wherein the abrasive grains are provided with a portion of a structure represented by Formula (2) below and an alkyl group on a surface of the abrasive grain, 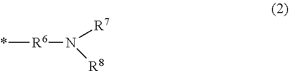
wherein in Formula (2), R⁶ represents a divalent organic group having a carbon number of 1 or more, R⁷ and R⁸ are each independently a hydrogen atom or a monovalent organic group having a carbon number of 1 or more, and * represents a bond.

7. The method for producing the abrasive grains as claimed in claim 1, wherein in the composition for chemical mechanical polishing that contains the abrasive grains, a zeta potential of the abrasive grains is 10 mV or more.

8. A composition for chemical mechanical polishing, containing:
abrasive grains produced according to the method according to claim 1; and
a liquid medium.

9. A composition for chemical mechanical polishing, comprising: abrasive grains, and a liquid medium,
wherein the abrasive grains are provided with a portion of a structure represented by Formula (1) below on a surface of the abrasive grain, 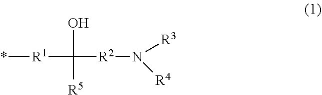
wherein in Formula (1), R¹ represents a single bond or a divalent organic group having a carbon number of 1 or more, R² represents a divalent organic group having a carbon number of 1 or more, and R³, R⁴, and R⁵ each independently represent a hydrogen atom or a monovalent organic group having a carbon number of 1 or more, and * represents a bond.

10. A composition for chemical mechanical polishing, comprising: abrasive grains, and a liquid medium,
wherein the abrasive grains have a portion of a structure represented by Formula (2) below and an alkyl group, 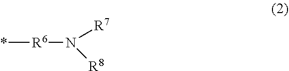
wherein in Formula (2), R⁶ represents a divalent organic group having a carbon number of 1 or more, R⁷ and R⁸ are each independently a hydrogen atom or a monovalent organic group having a carbon number of 1 or more, and * represents a bond.

11. The composition for chemical mechanical polishing as claimed in claim 8, wherein pH is 2 or more and 5 or less.

12. The composition for chemical mechanical polishing as claimed in claim 8, further comprising an acidic compound, an iron (III) compound, and an oxidization agent.

13. The composition for chemical mechanical polishing as claimed in claim 8, wherein the composition is used for polishing a silicon oxidization film.

14. The composition for chemical mechanical polishing as claimed in claim 12, wherein the composition is used for selectively polishing a tungsten film.

15. A polishing method, comprising a process of polishing a silicon oxide film by using the composition for chemical mechanical polishing as claimed in claim 8.

16. A polishing method, comprising a process of selectively polishing a tungsten film by using the composition for chemical mechanical polishing as claimed in claim 12.

17. The composition for chemical mechanical polishing as claimed in claim 9, wherein pH is 2 or more and 5 or less.

18. The composition for chemical mechanical polishing as claimed in claim 10, wherein pH is 2 or more and 5 or less.

19. The composition for chemical mechanical polishing as claimed in claim 9, further comprising an acidic compound, an iron (III) compound, and an oxidization agent.

20. The composition for chemical mechanical polishing as claimed in claim 10, further comprising an acidic compound, an iron (III) compound, and an oxidization agent.
